(19) United States
(12) Patent Application Publication
(10) Pub. No.: US 2009/0035951 A1
(43) Pub. Date: Feb. 5, 2009

(54) MANUFACTURING METHOD OF SEMICONDUCTOR DEVICE

(75) Inventors: Hironobu Miya, Toyama-shi (JP); Masanori Sakai, Takaoka-shi (JP); Norikazu Mizuno, Toyama-city (JP); Tsutomu Kato, Takaoka-shi (JP); Yuji Takebayashi, Toyama-shi (JP)

Correspondence Address: MATTINGLY, STANGER, MALUR & BRUNDIDGE, P.C., 1800 DIAGONAL ROAD, SUITE 370, ALEXANDRIA, VA, 22314, US

(73) Assignee: Hitachi Kokusai Electric Inc.

(21) Appl. No.: 12/171,756

(22) Filed: Jul. 11, 2008

(30) Foreign Application Priority Data
Jul. 20, 2007 (JP) 2007-189582
May 15, 2008 (JP) 2008-127978

(51) Int. Cl. H01L 21/31

(52) U.S. Cl. 438/787; 257/E21.24

(57) ABSTRACT

Provided is a manufacturing method of a semiconductor device composed of a step of carrying-in a wafer into a processing chamber; a step of forming an HfO₂ film on the wafer by alternately supplying TEMAH and O₃, under heating, into the processing chamber; and a step of carrying-out the wafer from the inside of the processing chamber, wherein in the step of forming the HfO₂ film, heating temperature of TEMAH and heating temperature of O₃ are set to be different.

### INCORPORATION BY REFERENCE

The present application claims priorities from Japanese applications JP2007-189582 filed on Jul. 20, 2007, and JP2008-127978 filed on May 15, 2008, the contents of which are hereby incorporated by reference into this application.

### BACKGROUND OF THE INVENTION

The present invention relates to a manufacturing method of a semiconductor device, and more specifically relates to technology effective in forming a metal oxide film on a substrate, which is a processing target.

With increasingly higher density of a semiconductor device, a high dielectric constant metal oxide such as HfO₂, ZrO₂ having high dielectric constant, has been noticed as a capacitor material. As a formation method of a high dielectric constant film, there is an ALD (Atomic Layer Deposition) film-formation method, which provides excellent embeddability into a concave part and step coverage.

In film formation of HfO₂ or ZrO₂, an amide compound such as tetrakis(ethylmethylamido)hafnium (TEMAH:Hf[N(C₂H₅)(CH₃)]₄) or tetrakis(ethylmethylamido)zirconium (TEMAZ:Zr[N(C₂H₅)(CH₃)]₄) is used mainly as a metal raw material. As an oxide, water or O₃ is used, however, in recent years, O₃ has been used mainly because of providing excellent film characteristics. In the ALD film-formation, TEMAH or TEMAZ, which is a metal material, and O₃, which is an oxidizing agent, are alternately supplied into a reaction chamber.

However, in a formation method of the metal oxide film at low temperature by using the ALD method, for example, in the case of forming the HfO₂ film, formation of the HfO₂ film in a state that ozone, which is an oxidizing agent, is not activated sufficiently, cannot provide not only desired film-formation rate but also raises problems such as decreased film thickness at the wafer center part of a patterned wafer having a trench (channel) structure, resulting in deteriorated step coverage, and reduced coverage property of the HfO₂ film due to loading number of the patterned wafers in a batch, or variation of film thickness caused by low or high pattern density (such a phenomenon is called loading effect).

In this case, increase in supply amount or supply time of ozone, which is an oxidizing agent, in order to improve step coverage or loading effect, by increased film-formation rate, may enhance film-formation rate and improve step coverage or loading effect, however, incurs increase in film-formation time, resulting in deterioration of throughput, or increase in production cost due to increase in consumption amount of raw materials, which may bring about deterioration of COO (Cost of Ownership: production cost per one sheet). As an example of these conventional technologies, there are JP-A-2005-259966, and JP-A-2006-66587.

### SUMMARY OF THE INVENTION

It is a major object of the present invention to provide a manufacturing method of a semiconductor device, which is capable of improving covering property or loading effect of the oxide film without increasing supply amount or supply time of the oxidizing agent, in formation of the oxide film.

In order to solve the above problems, there is provided, according to the present invention, a manufacturing method of a semiconductor device having:

a step of carrying-in at least one sheet of a substrate into a processing chamber;

a step of forming an oxide film onto the substrate by alternately supplying a first reactant and a second reactant containing an oxygen atom, into the processing chamber, under heating the substrate; and

a step of carrying-out the substrate from the inside of the processing chamber,

wherein in the step of forming the oxide film, substrate temperature is equal to or lower than self-decomposition temperature of the first reactant, and still more in the case where ozone is used as the second reactant, ozone is supplied by being heated at higher temperature than substrate temperature.

According to the present invention, in the step of forming the oxide film, heating temperature of the first reactant and heating temperature of the second reactant, which corresponds to the oxidizing agent, are set to be different, therefore, for example, by setting heating temperature of the second reactant higher than heating temperature of the first reactant, the second reactant can be supplied onto the substrate in an activated state without deactivation.

Accordingly, in formation of the metal oxide film, covering property or loading effect can be improved by increasing film-formation rate of the oxide film, without increasing supply amount or supply time of the second reactant, which corresponds to an oxidizing agent, resulting in avoiding beforehand deterioration of throughput or COO.

Other objects, features and advantages of the invention will become apparent from the following description of the embodiments of the present invention taken in conjunction with the accompanying drawings.

### BRIEF DESCRIPTION OF THE DRAWINGS

FIG. 1 is a drawing for schematically explaining adsorption of an oxide film raw material onto a Si substrate surface, and ozone oxidation in a preferable embodiment of the present invention.

FIG. 2 is a drawing for schematically explaining temperature dependence of ozone concentration in a preferable embodiment of the present invention.

FIG. 3 is a perspective view showing schematic configuration of a manufacturing apparatus of a semiconductor device used in a preferable embodiment of the present invention.

FIG. 4 is a side perspective view showing schematic configuration of a manufacturing apparatus of a semiconductor device used in a preferable embodiment of the present invention.

FIG. 5 is a schematic block diagram of a processing furnace and members accompanying therewith used in a preferable embodiment of the present invention, and in particular, a longitudinal cross-sectional view of the processing furnace part.

FIG. 6 is a cross-sectional view along the A-A line of FIG. 5.

FIG. 7 is a longitudinal cross-sectional view showing schematic configuration of a processing furnace and nearby parts thereof used in a preferable embodiment of the present invention.

FIG. 8 is a partial cross-sectional view showing schematic configuration of a nozzle for supplying ozone used in a preferable embodiment of the present invention.

FIG. 9 is a cross-sectional view along the B-B line of FIG. 8.

FIG. 10 is a drawing for explaining a schematic step of a manufacturing method of a semiconductor device relevant to a preferable embodiment of the present invention.

### DESCRIPTION OF THE EMBODIMENTS

Explanation will be given below on preferable embodiments of the present invention with reference to drawings.

### [Film-Formation Principle]

First, explanation will be given on film-formation principle, with an example of a step (metal oxide film formation step) of forming an HfO₂ film by the ALD method, by using tetrakis(ethylmethylamido)hafnium (TEMAH) and O₃.

Consideration will be given on a thermal decomposition process when TEMAH and O₃ are introduced into a processing chamber.

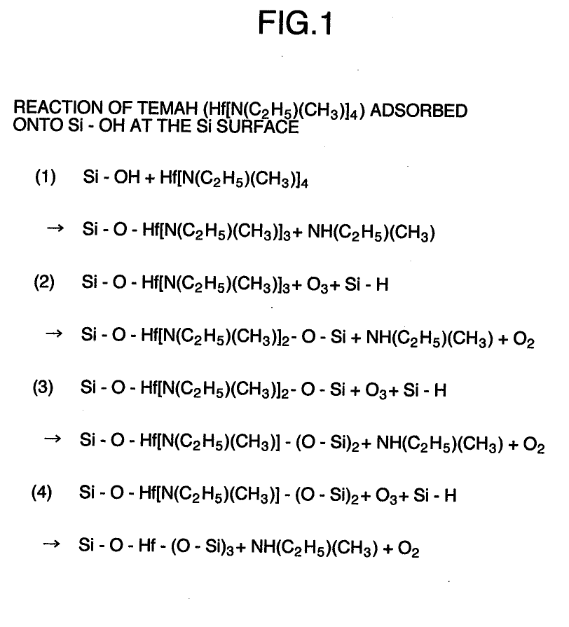

As shown in FIG. 1, there is a bonding of Si—H and Si—OH on an Si substrate. When TEMAH is supplied into the processing chamber, as shown in FIG. 1 (1), the TEMAH is adsorbed onto Si—OH to release ethylmethylamine NH(C₂H₅)(CH₃).

After that, O₃ is supplied into the processing chamber. Supply of O₃, as shown in FIG. 1 (2), further releases ethylmethylamine N(C₂H₅)(CH₃), which binds to a TEMAH molecule, and forms a Hf—O—Si bond. Still more supply of O₃, as shown in FIG. 1 (3) and FIG. 1 (4), forms a bond such as represented by Si—O—Hf[N(C₂H₅)(CH₃)]—(O—Si)₂ or Si—O—Hf—(O—Si)₃. That is, in an initial stage, an Hf molecule releases ethylmethylamine NH(C₂H₅)(CH₃), and sequentially forms a Hf—O—Si with Si on the substrate.

Here, when consideration will be given on a thermal decomposition process of O₃, which is an oxidization agent, in the processing chamber, S. W. Benson and A. E. Axworthy Jr. showed the O₃ decomposition by the following formulae (1) and (2) (Ozone Handbook, published by Japan Ozone Association).

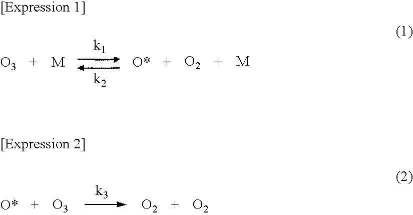

In the formula (1), “M” represents a third substance such as N₂, O₂, CO₂, O₃.

Reactions of the formula (1) and the formula (2) are represented by the formula (3).

$$\begin{matrix}[ Expression 3 ] & \\ \frac{1}{{[ {O}_{3} ]}_{t}} = \frac{2 {k}_{1} {k}_{3}}{{k}_{2} [ {O}_{2} ]} t \frac{1}{{[ {O}_{3} ]}_{s}} & ( 3 )\end{matrix}$$

In the formula (3), [O₃]ₜ represents ozone concentration after t hours; [O₂] represents oxygen concentration; [O₃]ₛ represents ozone concentration at the initial stage; and [t] represents elapsed time.

In the formula (1) and the formula (2), “k₁”, “k₂” and “k₃” are represented by the formula (4) to the formula (6).

K₁=(4.61±0.25)×10¹⁵exp(−24000/RT)cm³/mols⁻¹ (in the case of M=O₃) (4)

K₂=(6.00±0.33)×10¹⁵exp(+600/RT)cm³/mols⁻¹ (5)

K₃=(2.96±0.21)×10¹⁵exp(−6000/RT)cm³/mols⁻¹ (6)

A substance contributing to a reaction is an ozone radial (O*). In the case where O* is supplied to an Si substrate mounted at multiple stages in a batch type film-formation apparatus, insufficient amount of O* suppresses sufficient proceeding of the reaction with TEMAH, for example, provides bad effect such as insufficient film-formation rate, or deteriorated characteristics of step coverage or loading effect at the center part of the Si substrate. In order to increase O* in the formula (1) and the formula (3), it is necessary to increase flow amount of O₃ to be supplied to the processing chamber or raise O₃ gas temperature.

In a preferable embodiment of the present invention, there is provided a method for effectively increasing ozone concentration as compared with conventional ozone supply.

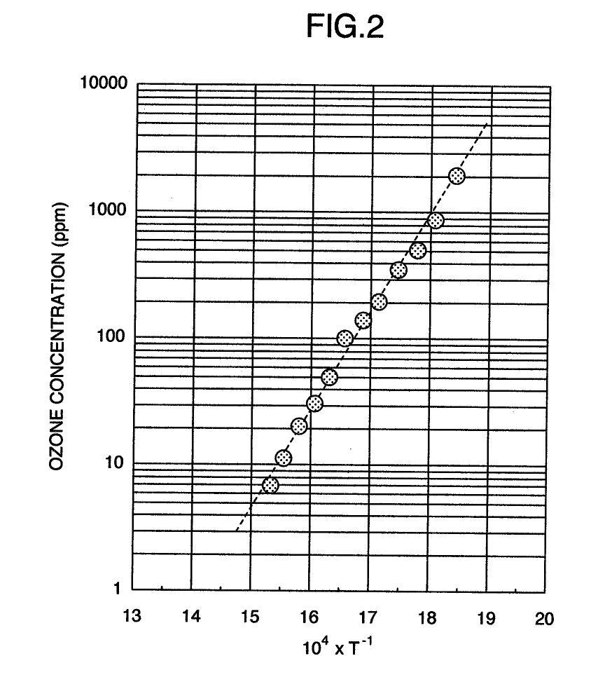

As shown in FIG. 2, ozone concentration in gas phase decreases with increase in temperature.

For example, in the case where O₃ with a concentration of 17000 ppm as O₃/O₂, is heated, ozone concentration at 300° C. is 350 ppm, on the other hand, ozone concentration at 400° C. is 4 ppm. Only by increasing temperature by 100° C., from 300° C. to 400° C., ozone concentration decreases to about 1/70 to 1/80.

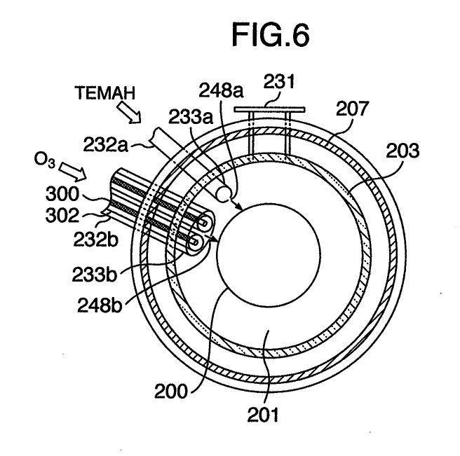

According to the formula (1), in the case where ozone concentration decreases, decomposition of one mole of O₃ generates 1 mole of O*. That is, generation amount of O* increases by about 70 to 80 times, by increasing temperature of a field, where these substances are present, from 300° C. to 400° C. Thus generated O* reduces substantial concentration in a reversed reaction of the formula (1), or by reaction with O₂ or O₃, as shown by the formula (2). In order to suppress these reactions, it is necessary to generate O* at the vicinity of the Si substrate, which is a supply target. As this method, in a preferable embodiment of the present invention, a method for installing a heater inside a nozzle for supplying O₃ into the processing chamber, and heating O₃ during supply by the heater (see the following description and FIG. 6 to FIG. 9) is adopted.

### [Total Configuration of the Apparatus]

Explanation will be given in more detail on a manufacturing apparatus of a semiconductor device or a manufacturing method thereof, relevant to a preferable embodiment of the present invention, based on the items explained in the above “Film-formation principle”.

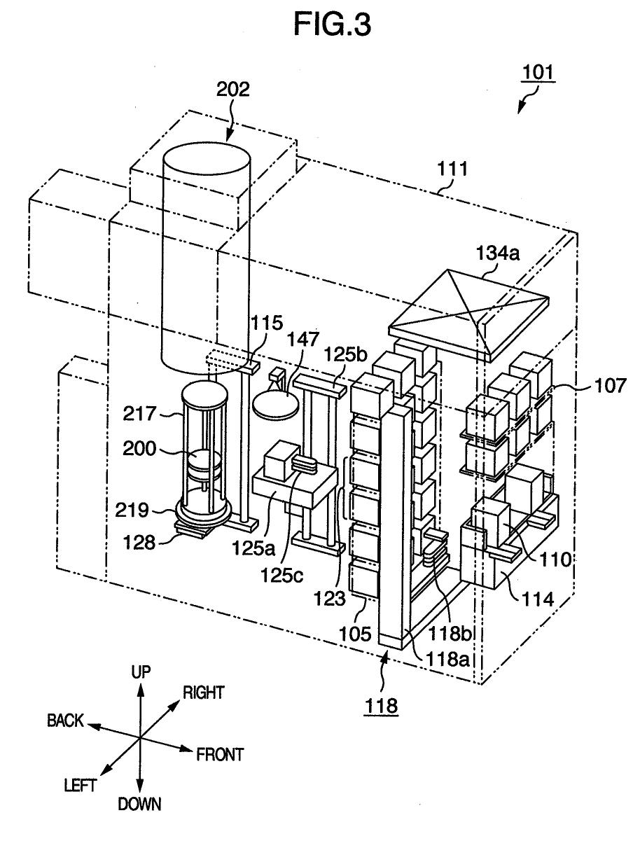

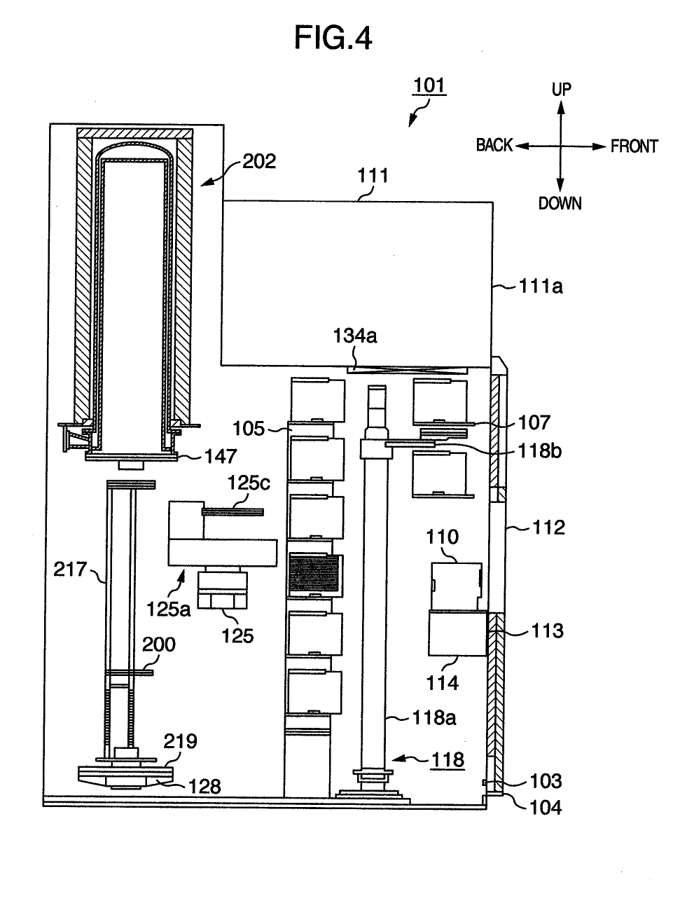

First, explanation will be given on a manufacturing apparatus of a semiconductor device used in a processing step in a manufacturing method of a semiconductor device, relevant to a preferable embodiment of the present invention, with reference to FIG. 3 and FIG. 4.

As shown in FIG. 3 and FIG. 4, in the manufacturing apparatus 101 of a semiconductor device, a cassette 110 is used, as a wafer carrier, which stores a wafer 200, made of a material such as silicon.

The manufacturing apparatus 101 of a semiconductor device is provided with a housing 111. At the lower part of a front wall 111a of the housing 111, a front maintenance port 103 is installed as an opening installed so that maintenance is possible. At the front maintenance port 103, a front maintenance door 104 is installed, which is opening and closing free.

At the front maintenance door 104, a cassette carrying-in and carrying-out 112 is installed so as to communicate inside and outside of the housing 111, and the cassette carrying-in and carrying-out 112 is designed to be opened and closed by a front shutter 113.

At the inside of the housing 111 of the cassette carrying-in and carrying-out 112, a cassette stage 114 is installed. The cassette 110 is designed to be carried-in on the cassette stage 114, or carried-out from the cassette stage 114, by an in-plant carrying apparatus (not shown).

The cassette stage 114 is installed so that the wafer 200 retains a vertical position inside the cassette 110, and a wafer carrying-in and carrying-out of the cassette 110 faces an upward direction, by the in-plant carrying apparatus. The cassette stage 114 is configured so that the cassette 110 is rotated 90 degree clockwise in a longitudinal direction to backward of the housing 111, and the wafer 200 inside the cassette 110 takes a horizontal position, and the wafer carrying-in and carrying-out of the cassette 110 faces backward of the housing 111.

At nearly the center-lower part in a front and back direction in the housing 111, a cassette shelf 105 is installed. The cassette shelf 105 is configured so that a plurality of the cassettes 110 are stored over a plurality of steps and a plurality of rows. At the cassette shelf 105, a transfer shelf 123 is installed where the cassettes 110, which are carrying targets of a wafer transfer mechanism 125, are stored. In addition, at the upward of the cassette stage 114, a standby cassette shelf 107 is installed, and configured so that a standby cassette 110 is stored.

Between the cassette stage 114 and the cassette shelf 105, a cassette carrying apparatus 118 is installed. The cassette carrying apparatus 118 is configured by a cassette elevator 118a, which is capable of ascending and descending the cassette 110 under holding, and a cassette carrying mechanism 118b as a carrying mechanism. The cassette transfer apparatus 118 is designed to carry the cassette 110 among the cassette stage 114, the cassette shelf 105 and the standby cassette shelf 107, by continuous motions of the cassette elevator 118a and the cassette carrying mechanism 118b.

At the backward of the cassette shelf 105, a wafer transfer mechanism 125 is installed. The wafer transfer mechanism 125 is configured by a wafer transfer apparatus 125a that is capable of rotating or linearly moving the wafer 200 in a horizontal direction, and a wafer transfer apparatus elevator 125b for ascending and descending the wafer transfer apparatus 125a. The wafer transfer apparatus elevator 125b is installed at the right side end part of the housing 111. The wafer transfer mechanism 125 is configured so as to pick-up the wafer 200 by a tzweezers 125c of the wafer transfer apparatus 125a, and charge the wafer 200 onto a boat 217, or discharge the wafer 200 from the boat 217, by continuous motions of the wafer transfer apparatus 125a and the wafer transfer apparatus elevator 125b.

As shown in FIG. 3 and FIG. 4, at the upward of the rear part of the housing 111, a processing furnace 202 is installed. The lower end part of the processing furnace 202 is configured so as to be opened and closed by a throat shutter 147.

At the downward of the processing furnace 202, there is installed a boat elevator 115 for ascending and descending the boat 217 to and from the processing furnace 202. To the boat elevator 115, an arm 128 is connected as a connecting tool, and at the arm 128, a seal cap 219 as a cap body is installed horizontally. The seal cap 219 is one for supporting the boat 217 vertically, and is configured so as to be able to block the lower end part of the processing furnace 202.

The boat 217 is installed with a plurality of holding members, and is configured so as to hold a plurality of sheets (for example, from about 50 to 150 sheets) of wafers 200 each horizontally, in a state that the centers thereof are aligned and installed in a vertical direction.

As shown in FIG. 3 and FIG. 4, at the upward of the cassette shelf 105, a clean unit 134a is installed for supplying clean air, that is, purified atmosphere. The clean unit 134a is configured by a supply fan and a dust-proof filter, so as to flow clean air through the inside of the housing 111.

Also at the left side end part of the housing 111, which is at the opposite side of the wafer transfer apparatus elevator 125b and the boat elevator 115 side, a clean unit (not shown) is installed for supplying clean air. This clean unit is also configured by a supply fan and a dust-proof filter, in the same way as in the clean unit 134a. Clean air supplied from this clean unit flows through the vicinity of the wafer transfer apparatus 125a, the boat 217 and the like, and then exhausted outside of the housing 111.

Then, explanation will be given on movement of the manufacturing apparatus 101 of a semiconductor device.

As shown in FIG. 3 and FIG. 4, before supply of the cassette 110 onto the cassette stage 114, the cassette carrying-in and carrying-out 112 is opened by the front shutter 113. After that, the cassette 110 is carried-in onto the cassette stage 114 from the cassette carrying-in and carrying-out 112. In this time, the cassette 110 is mounted so that the wafer 200 inside the cassette 110 is held in a vertical position, and the wafer carrying-in and carrying-out of the cassette 110 faces an upward direction.

After that, the cassette 110 is rotated 90 degree clockwise in a longitudinal direction, so that the wafer 200 inside the cassette 110 takes a horizontal position, and the wafer carrying-in and carrying-out of the cassette 110 faces backward of the housing 111, by the cassette stage 114.

Then, the cassette 110 is automatically carried and delivered at a specified shelf position of the cassette shelf 105 or the standby cassette shelf 107, by the cassette carrying apparatus 118 to be stored temporarily, and transferred to the transfer shelf 123 from the cassette shelf 105 or the standby cassette shelf 107, by the cassette carrying apparatus 118, or directly transferred to the transfer shelf 123.

When the cassette 110 is transferred to the transfer shelf 123, the wafer 200 is picked-up from the cassette 110 through the wafer carrying-in and carrying-out by the tweezers 125c of the wafer transfer apparatus 125a, to be charged onto the boat 217 at the backward of a transfer chamber 124. The wafer transfer apparatus 125a after delivering the wafer 200 onto the boat 217 returns to the cassette 110, and charges the next wafer 200 onto the boat 217.

When predetermined sheets of the wafers 200 are charged onto the boat 217, the lower end part of the processing furnace 202, which was kept closed by the throat shutter 147, is released by the throat shutter 147. Subsequently, the boat 217 holding a group of wafers 200 is carried-in (loaded) inside the processing furnace 202, by ascending the seal cap 219 by the boat elevator 115.

After the loading, the wafer 200 is subjected to an optional processing (refer to the later description) in the processing furnace 202. After the processing, the cassette 110 and the wafer 200 are carried-out outside the housing 111, in a reversed order of the above.

### [Configuration of a Processing Furnace]

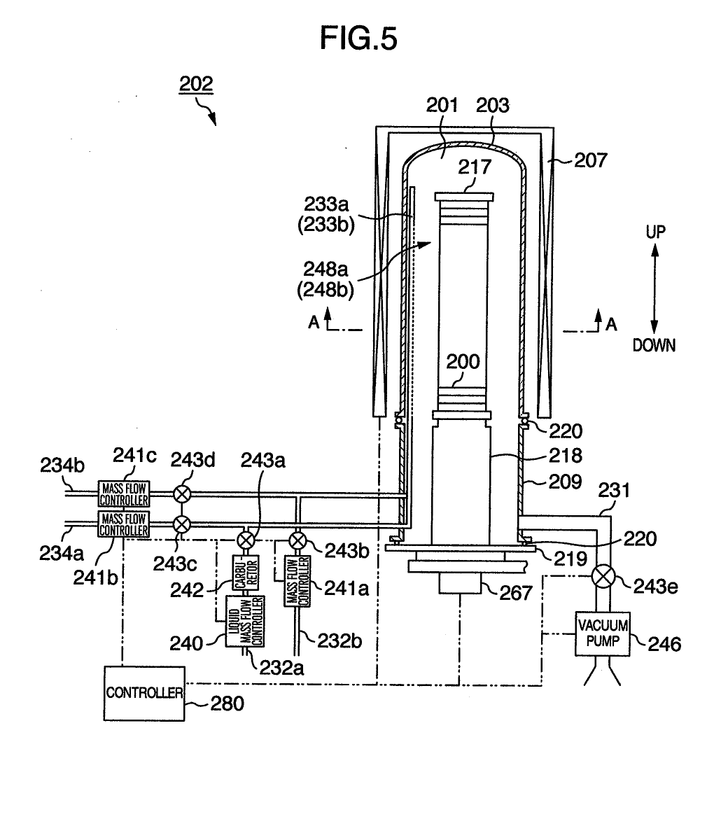

As shown in FIG. 5, at the processing furnace 202, a heater 207 is installed, which is a heating apparatus. At the inside of the heater 207, a reaction tube 203 is installed, which is capable of storing the wafer 200, which is an example of a substrate. The reaction tube 203 is made of quartz. At the downward of the reaction tube 203, a manifold 209 made of, for example, stainless steel or the like, is installed. At the lower part of the reaction tube 203 and the upper part of the manifold 209, a ring-like flange is each formed.

Between each of the flanges at the reaction tube 203 and the manifold 209, an O-ring 220 is installed, so as to air-tightly seal between the reaction tube 203 and the manifold 209. The lower part of the manifold 209 is air-tightly blocked by a seal cap 219, which is a cap body, via the O-ring 220. In the processing furnace 202, the processing chamber 201 is formed for processing the wafer 202, by at least the reaction tube 203, the manifold 209 and the seal cap 219.

At the seal cap 219, the boat 217, which is a substrate holding member, is installed via a boat support stand 218. The boat support stand 218 is designed to be a holding body so as to hold the boat 217. The boat 217 is installed at nearly the center part of the reaction tube 203 in a supported state by the boat support stand 218. At the boat 217, a plurality of the wafers 200, to be subjected to batch processing, are charged in multiple stages in an up and down direction in FIG. 5, while maintaining them in a horizontal position. The wafers 200 stored in the processing chamber 201 are designed to be heated at predetermined temperature by the heater 207.

The boat 217 is designed to ascend and descend freely in an up and down direction in FIG. 5, by the boat elevator 115 (refer to FIG. 3), and is capable of entering or coming out of (ascending and descending) the reaction tube 203. At the lower part of the boat 217, a boat rotation mechanism 267 is installed for rotating the boat 217 to enhance processing uniformity, and the boat 217 held at the boat support stand 218 is designed to be rotated by the boat rotation mechanism 267.

To the processing chamber 201, there are connected two gas supply pipelines 232a and 232b for supplying two kinds of gases.

At the gas supply pipeline 232a, a liquid mass flow controller 240, which is a flow amount controlling apparatus, a carburetor 242 and a valve 243a, which is an open-close valve, are installed in this order from the upstream side. To the gas supply pipeline 232a, there is connected a carrier gas supply pipeline 234a for supplying carrier gas. At the carrier gas supply pipeline 234a, there are installed a mass flow controller 241b, which is a flow amount controlling apparatus, and a valve 243c, which is an open-close valve, in this order from the upstream side.

The end part of the gas supply pipeline 232a is connected to a nozzle 233a made of quartz. The nozzle 233a is extending in an up and down direction in FIG. 5, in arc-like space between the inside wall of the reaction tube 203 and the wafer 200, which configure the processing chamber 201. At the side surface of the nozzle 233a, a plurality of gas supply holes 248a are formed. The gas supply holes 248a each have the same opening area and are formed in the same opening pitch over from the lower part to the upper part.

At the gas supply pipeline 232b, a mass flow controller 241a, which is a flow amount controlling apparatus, and a valve 243b, which is an open-close valve, are installed in this order from the upstream side. To the gas supply pipeline 232b, there is connected a carrier gas supply pipeline 234b for supplying carrier gas. At the carrier gas supply pipeline 234b, there are installed a mass flow controller 241c, which is a flow amount controlling apparatus, and a valve 243d, which is an open-close valve, in this order from the upstream side.

The end part of the gas supply pipeline 232b is connected to a nozzle 233b made of quartz. The nozzle 233b is extending in an up and down direction in FIG. 5, in arc-like space between the inside wall of the reaction tube 203 and the wafer 200, which configure the processing chamber 201. At the side surface of the nozzle 233b, a plurality of gas supply holes 248b are formed. The gas supply holes 248b each have the same opening area and are formed in the same opening pitch over from the lower part to the upper part.

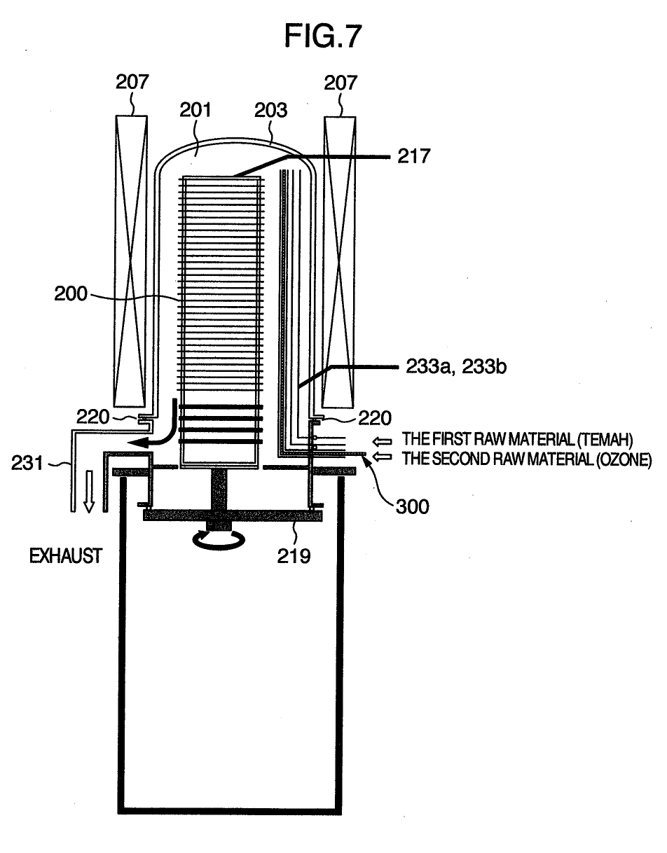

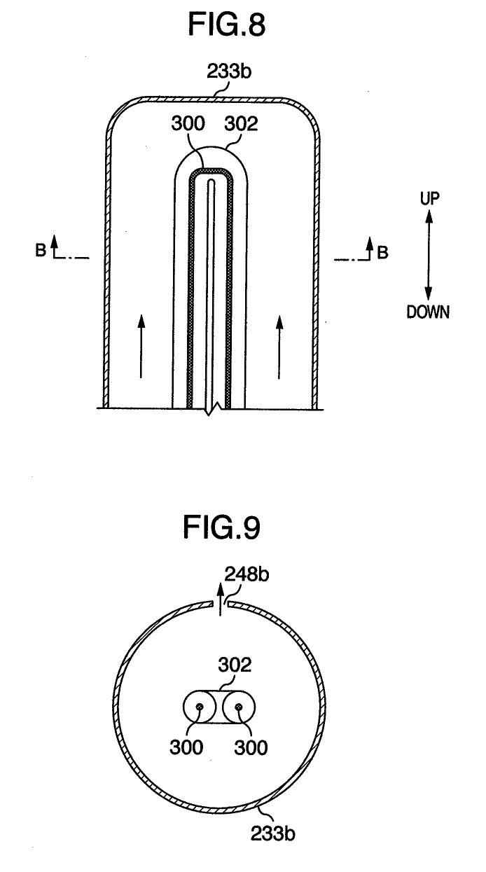

As shown in FIG. 6 to FIG. 9, at the inside of the nozzle 233b, there is installed a heater 300 (heater wires) for heating gas flowing through the nozzle 233b. As shown in FIG. 6, the heater 300 is communicated from the end part of the gas supply pipeline 232b to the nozzle 232b. As shown in FIG. 7, the heater 300 is extending in an up and down direction, in space formed between the inside wall of the reaction tube 203 and the boat 217, and in particular, as shown in FIG. 8, is turned down at the upper part of the nozzle 232b.

As shown in FIG. 6, FIG. 8 and FIG. 9, the heater 300 is covered with a protection tube 302 made of quartz. The protection tube 302 takes a reversed U-character shape along a turning down part (refer to FIG. 8) of the heater 300, and completely covers the heater 300. In the present embodiment, when gas flows into the nozzle 233b, the gas can be supplied into the processing chamber 201 from the gas supply holes 248b under heating by the heater 300.

As shown in FIG. 5, to the processing chamber 201, there is connected one end part of a gas exhaust pipeline 231 for exhausting atmosphere inside the processing chamber 201. The other end part of the gas exhaust pipeline 231 is connected to a vacuum pump 246, so as to be able to evacuate inside of the processing chamber 201. At the gas exhaust pipeline 231, a valve 243d is installed. The valve 243d is an open-close valve which enables not only to evacuate the processing chamber 201, or stop evacuation of the processing chamber 201 by opening and closing the valve, but also adjust pressure by adjusting valve opening degree.

Each of the above members, the liquid mass flow controller 240, the mass flow controllers 241a to 241c, the valves 243a to 243e, the heaters 207 and 300, the vacuum pump 246, the boat rotation mechanism 267, the boat elevator 115 and the like, is connected to a controller 280, which is a control unit.

The controller 280 is designed so as to control flow amount adjustment of the liquid mass flow controller 240, flow amount adjustment of the mass flow controllers 241a to 241c, open-close movement of the valves 243a to 243d, open-close and pressure adjustment movements of the valve 243e, temperature adjustments of the heaters 207 and 300, start and stop of the vacuum pump 246, rotation speed adjustment of the boat rotation mechanism 267, ascending and descending motions of the boat elevator 115 and the like.

### [A Manufacturing Method of a Semiconductor Device]

Then, explanation will be given on a manufacturing method of a semiconductor device relevant to a preferable embodiment of the present invention, in particular, on a film-formation example by using the processing furnace 202.

In the processing furnace 202, it is possible to make film-formation of high dielectric constant film such as SiO₂, HfO₂, ZrO₂ onto the wafer 200.

As one component of the reactants, which are film-formation materials, in the case where a SiO₂ film is formed, TDMAS can be used; in the case where an HfO₂ film is formed, TEMAH, (tetrakis(ethylmethylamido)hafnium, Hf(NEtMe)₄), Hf(O-tBu)₄, TDMAH, (tetrakis (diethylamido) hafnium, Hf(NMe₂)₄), TDEAH, (tetrakis(diethylamido)hafnium, Hf(NEt₂)₄), Hf(MMP)₄ or the like can be used; and in the case where a ZrO₂ film is formed, in the same way as in formation of the HfO₂ film, Zr(NEtMe)₄, Zr(O-tBu)₄, Zr(NMe₂)₄, Zr(NEt₂)₄, Zr(MMP)₄ or the like can be used. In the above chemical formulae, “Et” represents C₂H₅, “Me” represents CH₃, “O-tBu” represents O(CH₃)₃, and “MMP” represents OC(CH₃)₂CH₂OCH₃.

It should be noted that as the other component of the reactants, O₃ can be used.

In the present embodiment, explanation will be given on an example of forming a film onto the wafer 200, by using TEMAH and O₃ as reactants, in an example of film-formation processing by using the ALD method.

The ALD (Atomic Layer Deposition) method is a method for executing film-formation by utilization of a surface reaction, by alternately supplying reactive gasses, which are at least two kinds of raw materials used in film-formation, one kind by one kind, under certain film-formation conditions (temperature, time and the like), and by adsorbing them onto a substrate by one atomic layer unit. In this case, control of film thickness is carried out by cycle number of supplying the reactive gas (for example, in the case where film-formation rate is 1 Å/cycle, then 20 cycles of film-formation processing is carried out to obtain a film of 20 Å).

In the ALD method, in the case where, for example, an HfO₂ film is formed, high quality film-formation is possible at a low temperature of 180 to 300° C., by using TEMAH and O₃.

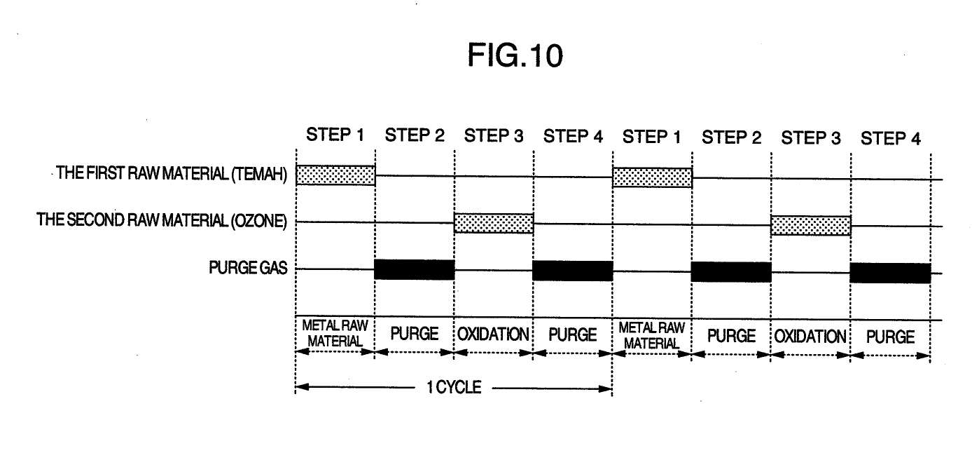

First, as described above, the wafer 200 is charged onto the boat 217 and carried-in to the processing chamber 201. After carrying-in the boat 217 to the processing chamber 201, 4 steps to be described below, are carried out sequentially, and repeated from the step 1 to the step 4 until the HfO₂ film with predetermined film thickness is formed (refer to FIG. 10).

### (Step 1)

TEMAH is flown to the gas supply pipeline 232a, and carrier gas is flown to the carrier gas supply pipeline 234a. As this carrier gas, He (helium), Ne (neon), Ar (argon), N₂ (nitrogen) or the like can be used, and in particular, in the present embodiment, N₂ is used. The valve 243a of the gas supply pipeline 232a is opened.

TEMAH flows through the gas supply pipeline 232a under flow amount adjustment by the liquid mass flow controller 240, and is vaporized in mid-course by the carburetor 242. Vaporized TEMAH gas flows in the nozzle 233a from the gas supply pipeline 232a, is supplied to the processing chamber 201 from the gas supply holes 248a, and exhausted from the gas exhaust pipeline 231.

In this case, by suitable adjustment of the valve 243e of the gas exhaust pipeline 231, pressure inside the processing chamber 201 is maintained within a range of from 26 to 266 Pa, for example, 66 Pa. In addition, by control of the heater 207, temperature of the wafer 200 is set within a range of from 180 to 300° C., for example, 200° C.

In the above step 1, vaporized TEMAH gas is supplied to the processing chamber 201 and TEMAH is adsorbed at the surface of the wafer 200.

### (Step 2)

The valve 243a of the gas supply pipeline 232a is closed to stop supply of TEMAH. In this case, the valve 243e of the gas exhaust pipeline 231 is maintained open, and inside the processing chamber 201 is exhausted by the vacuum pump 246 until the pressure becomes 20 Pa or lower, to exhaust residual vaporized TEMAH gas inside the processing chamber 201, from inside the processing chamber 201.

After exhausting inside the processing chamber 201 for predetermined time, the valve 243c of the carrier gas supply pipeline 234a is opened, in a state that the valve 243a of the gas supply pipeline 232a is closed. Carrier gas having flow amount adjusted by the mass flow controller 241b, is supplied into the processing chamber 201 to replace the processing chamber 201 with N₂.

### (Step 3)

O₃ gas is flown to the gas supply pipeline 232b, and carrier gas is flown to the carrier gas supply pipeline 234b. As this carrier gas, He (helium), Ne (neon), Ar (argon), N₂ (nitrogen) or the like can be used, and in particular, in the present embodiment, N₂ is used. The valve 243b of the gas supply pipeline 232b, and the valve 243d of the carrier gas supply pipeline 234b are opened.

Carrier gas flows through the carrier gas supply pipeline 234b under flow amount adjustment by the mass flow controller 241c, and flows in the gas supply pipeline 232b from the carrier gas supply pipeline 234b. On the other hand, O₃ gas flows through the gas supply pipeline 232b under flow amount adjustment by the mass flow controller 241a, and is mixed with carrier gas in the mid-course thereof. O₃ gas flows into the nozzle 233b from the gas supply pipeline 232b in a mixed state with carrier gas, flows through space between the inside wall of the nozzle 233b and the protection tube 302 inside the nozzle 233b, supplied to the processing chamber 201 from the gas supply holes 248b, and exhausted from the gas exhaust pipeline 231.

In this case, by suitable adjustment of the valve 243e of the gas exhaust pipeline 231, pressure inside the processing chamber 201 is maintained within a range of from 26 to 266 Pa, for example, 66 Pa. Time of O₃ gas exposure to the wafer 200 is set roughly from 10 to 120 seconds. The heater 207 is set so that temperature of the wafer 200 becomes, in the same way as in supplying vaporized TDMAS gas in the step 1, within a range of from 180 to 300° C., for example 200° C.

In the step 3, heating temperature of O₃ gas inside the nozzle 233b is different from control temperature inside the processing chamber 201 in the step 1 (in supplying TEMAH), or control temperature inside the processing chamber 201 in the step 3, and heating temperature of O₃ gas inside the nozzle 233b is set at higher temperature than these control temperatures. For example, in the case where inside the processing chamber 201 is controlled at 200° C. by controlling the heater 207, temperature of the nozzle 233b is controlled at 300 to 400° C. by controlling the heater 300.

This is because, as explained in the above “Film-formation principle”, decomposition of O₃ depends on temperature, and in the case where inside the processing chamber 201 is set at low temperature, decomposition of O₃ is not carried out sufficiently, resulting in insufficient supply of O₃ radicals. Therefore, in the step 3, O₃ gas is heated at high temperature inside the nozzle 233b, so that ozone radicals can be supplied sufficiently to the wafer 200.

In the above step 3, O₃ gas is supplied to the processing chamber 201, and TEMAH already adsorbed at the surface of the wafer 200 and O₃ are reacted to form the HfO₂ film onto the wafer 200.

### (Step 4)

The valve 243b of the gas supply pipeline 232b is closed to stop supply of O₃ gas. In this case, the valve 243e of the gas exhaust pipeline 231 is maintained open, and inside the processing chamber 201 is exhausted by the vacuum pump 246 until the pressure becomes 20 Pa or lower, to exhaust residual O₃ gas inside the processing chamber 201, from inside the processing chamber 201.

After exhausting inside the processing chamber 201 for predetermined time, the valve 243d of the carrier gas supply pipeline 234b is opened, in a state that the valve 243b of the gas supply pipeline 232b is closed. Carrier gas, having flow amount thereof adjusted by the mass flow controller 241c, is supplied into the processing chamber 201 to replace the processing chamber 201 with nitrogen.

In the present embodiment above, the heater 300 is installed inside the nozzle 233b, and in the step 3, O₃ gas is supplied to the wafer 200 in a state, that heating temperature of O₃ gas is higher than heating temperature of TDMAS or temperature inside the processing chamber 201, by heating O₃ gas by the heater 300, therefore, it is considered that ozone radicals generated from O₃ gas are supplied onto the wafer 200 in an activated state without deactivation. Accordingly, in formation of the HfO₂ film, covering property or loading effect of the HfO₂ film can be improved without increasing supply amount or supply time of O₃ gas, which corresponds to an oxidizing agent, resulting in avoiding beforehand deterioration of throughput or COO.

It should be noted that in a manufacturing method of a semiconductor device relevant to the present embodiment, explanation was given above by assuming the case where the HfO₂ film is formed as a metal oxide film, however, accompanying with change of a reactant or a film kind, for example, temperature inside the processing chamber 201, which is controlled by the heater 207, may be changed as appropriate, within a range of from 20 to 600° C., and in the case where the ZrO₂ film is formed by TEMAZ and O₃ gas, within a range of from 180 to 300° C.; or heating temperature of a reactant (a substance corresponding to an oxidizing agent such as O₃ or the like), which is controlled by the heater 300, may be changed as appropriate, within a range of from 20 to 600° C., preferably within a range of from 300 to 400° C.

Temperature inside the processing chamber 201 is determined by characteristics of a first raw material. For example, in the case where the first raw material is TEMAH, self-decomposition temperature determined with ARC (Accelerating Rate Calorimeter) or SC-DSC (Sealed Cell Differential Scanning Calorimeter) is 271° C., and decomposition is abruptly started when temperature is over this temperature. On the other hand, O₃ gas, which is a second raw material, seldom decomposes at equal to or lower than 200° C. Therefore, in a system of TEMAH and O₃ gas, a processing chamber temperature of from 200 to 250° C. is used. In the case where the first raw material is trisdimethylaminosilane, TDMAS, self-decomposition temperature is 508° C. In the case where an SiO₂ film is formed in a system of TDMAS and O₃ gas, sufficient O₃ decomposition can be prospected in film-formation at a temperature region of from 300 to 500° C., however, in the case where film-formation is carried out at equal to or lower than 300° C., in the same way as in TEMAH, heating temperature of an oxidizing agent such as O3, which is the second reactant, is changed as appropriate within a range of from 20 to 600° C., preferably within a range of from 300 to 400° C.

Explanation was given above on preferable embodiments of the present invention, and according to a preferable embodiment of the present invention, there is provided:

A manufacturing method of a semiconductor device having:

a step of carrying-in at least one sheet of a substrate into a processing chamber;

a step of forming an oxide film onto the substrate by alternately supplying a first reactant and a second reactant containing an oxygen atom, under heating, into the processing chamber; and

a step of carrying-out the substrate from the inside of the processing chamber,

wherein, in the step of forming the oxide film, heating temperature of the first reactant and heating temperature of the second reactant are set to be different.

According to other embodiment of the present invention, there is provided:

A second manufacturing method of a semiconductor device having:

a step of carrying-in at least one sheet of a substrate into a processing chamber;

a step of forming an oxide film onto the substrate by alternately supplying a first reactant and a second reactant containing an oxygen atom, under heating, into the processing chamber, as well as by heating the substrate; and

a step of carrying-out the substrate from the inside of the processing chamber,

wherein, in the step of forming the oxide film, heating temperature of the second reactant is made higher than heating temperature of the substrate.

According to the second manufacturing method of a semiconductor device, in the step of forming the oxide film, heating temperature of the second reactant, which corresponds to an oxidizing agent, is made higher than heating temperature of the substrate, therefore, the second reactant can be supplied onto the substrate in an activated state without deactivation. Accordingly, in formation of the metal oxide film, covering property or loading effect of the oxide film can be improved without increasing supply amount or supply time of the second reactant, which corresponds to an oxidizing agent, resulting in avoiding beforehand deterioration of throughput or COO.

According to other preferable embodiment of the present invention, there is provided a first manufacturing apparatus of a semiconductor device installed with a processing chamber for processing at least one sheet of a substrate, a first heater for heating the processing chamber, a first supply member for supplying a first reactant into the processing chamber, a second supply member for supplying a second reactant containing an oxygen atom into the processing chamber, a second heater installed inside the second supply member, for heating the second reactant, and an exhaust system for exhausting atmosphere inside the processing chamber.

According to the first manufacturing apparatus of a semiconductor device, because the second heater is installed inside the second supply member, temperature of the second reactant is made higher than temperature of the substrate in the processing chamber, by heating the second reactant flowing through the second supply member, and the second reactant can be supplied in this state onto the substrate, therefore, the second reactant, which corresponds to an oxidizing agent, can be supplied onto the substrate in an activated state without deactivation. Accordingly, in formation of the metal oxide film, covering property or loading effect of the oxide film can be improved without increasing supply amount or supply time of the second reactant, which corresponds to an oxidizing agent, resulting in avoiding beforehand deterioration of throughput or COO.

There is provided a second manufacturing apparatus of a semiconductor device, wherein in the first manufacturing apparatus of a semiconductor device, the second heater is preferably covered with a protecting member.

According to the second manufacturing apparatus of a semiconductor device, because the second heater is covered with the protecting member, in the case where the second reactant flows through the second supply member, adhesion of the second reactant onto the second heater can be prevented.

It should be further understood by those skilled in the art that although the foregoing description has been made on embodiments of the invention, the invention is not limited thereto and various changes and modifications may be made without departing from the spirit of the invention and the scope of the appended claims.

1. A manufacturing method of a semiconductor device comprising:
a step of carrying-in at least one sheet of a substrate into a processing chamber;
a step of forming an oxide film onto said substrate by alternately supplying a first reactant and a second reactant containing an oxygen atom, into the processing chamber, under heating said substrate; and
a step of carrying-out said substrate from the inside of said processing chamber,
wherein in the step of forming said oxide film, substrate temperature is equal to or lower than self-decomposition temperature of said first reactant, and still more in the case where ozone is used as said second reactant, ozone is supplied by being heated at higher temperature than substrate temperature.

2. The manufacturing method of a semiconductor device according to claim 1, wherein in the step of forming said oxide film, and still more in the case where ozone is used as said second reactant, heating temperature of ozone is from 300° C. to 600° C.

3. The manufacturing method of a semiconductor device according to claim 1, wherein in the step of forming said oxide film, still more in the case where ozone is used as said second reactant, and the substrate is heated at equal to or lower than 300° C., heating temperature of ozone is from 300° C. to 600° C.
